(19) United States
(12) Patent Application Publication
(10) Pub. No.: US 2026/0093300 A1
(43) Pub. Date: Apr. 2, 2026

(54) EXPANDED FUNCTIONALITY OF AN ELECTRONIC DEVICE VIA A CLOSED-LOOP THERMAL SOLUTION

(71) Applicant: Apple Inc., Cupertino, CA (US)

(72) Inventors: Grant S. Haug, Mountain View, CA (US); Corey S. Provencher, Pittsfield, MA (US); Banafsheh Barabadi, Emerald Hills, CA (US)

(73) Assignee: Apple Inc., Cupertino, CA (US)

(21) Appl. No.: 18/900,484

(22) Filed: Sep. 27, 2024

(51) Int. Cl. G06F 1/20; G06F 1/16; H02J 50/10; H05K 7/20

(52) U.S. Cl. CPC G06F 1/206; G06F 1/1632; G06F 1/203; H02J 50/10; H05K 7/20136; H05K 7/20209

(57) ABSTRACT

Devices, methods, and structures for unleashing the full computing power of handheld and wearable computing devices. An example can provide a docking station that can help to overcome form factor limitations of handheld and wearable computing and other small form factor devices. These limitations can include a limited capability of a small form factor device to dissipate heat due and an inability to support large connectors due to a limited surface area.

### BACKGROUND

The number of types of electronic devices that are commercially available has increased tremendously the past few years and the rate of introduction of new devices shows no signs of abating. Devices such as tablet computers, laptop computers, all-in-one computers, desktop computers, cell phones, storage devices, wearable-computing devices, portable media players, navigation systems, monitors, adapters, and others, have become ubiquitous.

Some of these devices, such as tablet computers, phones, wearable computing devices, and others (collectively referred to as handheld and wearable devices), possess a remarkable amount of computing power in a small form factor. The efficient size of these devices make the easy to carry in a pocket or bag, or to wear. But this small size can also create limitations for these powerful devices.

The high ratio of computing power to device size can cause complications. When used, computing power translates into the generation of heat. This heat is harder to dissipate from a small volume than from a large volume. The limited amount of heat that can be removed from a compact form as a function of time can restrict or otherwise limit the computing power that can be utilized for a sustained period. More specifically, running such a device at a high computational rate for a significant duration can cause heating of internal components. This can lead to a premature failure of the device.

The small size of these devices can also preclude an ability to include relatively large connectors at its surface. For example, connectors such as HDMI or some DisplayPort connectors can be too large to be incorporated by such a device.

Thus, what is needed are devices, methods, and structures for unleashing the full computing power of handheld and wearable computing devices.

### SUMMARY

Accordingly, embodiments of the present invention can provide devices, methods, and structures for unleashing the full computing power of handheld and wearable computing devices. An illustrative embodiment of the present invention can provide a docking station that can help to overcome form factor limitations of handheld and wearable computing and other small form factor devices.

A limitation of a small form factor electronic device can be its limited ability to dissipate heat to its environment. When such an electronic device is performing complicated computational and display tasks, such as can be present in a video game, heat generated by these tasks can raise internal temperatures. These higher internal temperatures can shorten an expect lifetime for an electronic device. To prevent this, an electronic device can throttle clock rate or other parameters to reduce internal temperatures to protect the electronic device. That is, the electronic device can apply one or more policies based on temperature, battery charge state, and other parameters to device clock rate, display brightness, and other device characteristics.

Accordingly, these docking stations can include one or more fans to pass air over some or all of the electronic device to provide cooling when the electronic device is mounted on the docking station. With this cooling, an electronic device can maintain a higher level of computational performance without being throttled by the policies of the electronic device. For example, a docking station can include a fan that draws air from openings in the docking station and moves air towards the electronic device. The air can be directed towards a portion of the electronic device that is expected to be heated the most. The air can emerge from openings in the docking station near the electronic device. For example, the air can emerge from a contacting surface that mates with the electronic device. The contacting surface can be permeable to allow air flow. For example, the contacting surface can be a mesh, cloth, plastic with holes, or other permeable contacting surface.

In another example, a docking station can include a fan that draws air from openings in the contacting surface and moves air towards openings in the docking station. The contacting surface can be a mesh, cloth, plastic with holes, or other permeable contacting surface. The air can be directed pulled from near a portion of the electronic device that is expected to be heated the most. The air can emerge from openings in the docking station.

In these and other embodiments of the present invention, a docking station can include more than one fan. For example, a docking station can include a first fan that draws air from openings in the docking station and a second fan that moves air towards the electronic device. The air can be directed by the second fan towards a portion of the electronic device that is expected to be heated the most. The air can emerge from openings in the docking station near the electronic device. For example, the air can emerge from a contacting surface that mates with the electronic device. The contacting surface can be permeable to allow air flow. For example, the contacting surface can be a mesh, cloth, plastic with holes, or other permeable contacting surface.

In another example, a docking station can include a first fan that draws air from openings in the contacting surface and a second fan that moves air towards openings in the docking station. The contacting surface can be a mesh, cloth, plastic with holes, or other permeable contacting surface. The air can be directed pulled by the first fan from near a portion of the electronic device that is expected to be heated the most. The air can be moved by the second fan to emerge from openings in the docking station.

These and other embodiments of the present invention can include other cooling components as well. For example, a docking station can include a thermoelectric cooler or other type of cooler. For example, a docking station can include a Peltier or other type of cooler. This cooler can be used to cool the air being delivered to the electronic device by the one or more fans of the docking station.

Another limitation of a small form factor electronic device can be its limited ability to include large connectors. This limitation can prevent an electronic device from being able to drive one or more monitors that are separate from the electronic device. Accordingly, embodiments of the present invention can provide docking stations that can include connectors for monitors and other accessory devices. These connectors can include HDMI connectors, full sized DisplayPort connectors, and other such connectors. These connectors can allow a handheld or portable computing device to drive one or more external monitors, storage devices, or other accessories via the docking station.

These docking stations can communicate with an electronic device in several ways. For example, a docking station and electronic device can communicate wirelessly using Wi-Fi, Bluetooth, Near-Field, or by using other wireless protocols. To reduce the amount of power needed for data transmission between a docking station and electronic device, a wired standard, such as Universal Serial Bus Type-C can be used. This can allow graphics data generated by an electronic device to be routed to the docking station, which can then provide data to a monitor over an HDMI, DisplayPort, or other type of cable.

These docking stations can include other types of communications circuits. For example, a docking station can include a Bluetooth circuit and antenna for communicating with a keyboard, mouse, trackpad, camera, aim controller, or other device. The docking station can include an ethernet connection for joining local area network, for example in a workplace environment.

The docking station can act as an intermediary to provide power to the electronic device. For example, a docking station can receive power from a power adapter a USB type C connector. The docking station can inductively couple this power to the electronic device. To facilitate this, the docking station can include a coil to transmit power to a corresponding coil in the electronic device. To align the electronic device to the docking station for power transfer, the docking station can include one or more magnets align with one or more magnets in the electronic device. Instead of magnets, one or more clips, suction cups, holders, or other structures can be used to secure an electronic device to a docking station. The signal used on these coils can be modulated to transfer data between the electronic device and the docking station. This information can be in regards to a state of a battery in the electronic device, a desired charge rate, or other information.

In these and other embodiments of the present invention, the speed of the one or more fans in the docking station can be controlled in a closed-loop fashion. In these and other embodiments of the present invention, the fan speed can be controlled primarily by the electronic device. In these embodiments of the present invention, an electronic device can include a temperature sensor and a battery monitor. Policy enforcement circuitry can receive information from the temperature sensor and the battery monitor. The policy enforcement circuitry can also receive inputs regarding current and upcoming activities of the electronic device as well as other characteristics of the electronic device. The policy enforcement circuitry can determine a desired speed of a fan control circuit in the docking station. The electronic device can provide this information to the docking station. The fan control circuit in the docking station can then adjust the one or more fans in the docking station. The fan control circuit in the docking station can further adjust any cooler included in the docking station. The docking station can further adjust any power being delivered to the electronic device based on a present state of a battery of electronic device, present and upcoming activities of the electronic device, as well as a present need to reduce power dissipation of the electronic device. The electronic device can communicate with power transmitting circuitry of the docking station over the inductive link used for charging, a wireless channel, or a wired channel, as discussed above.

In these and other embodiments of the present invention, the fan speed can be controlled primarily by the docking station. For example, the docking station can include a first temperature sensor positioned near a mounting location for the electronic device. From this, the docking station can approximate a temperature of the electronic device. The docking station can further include a second temperature sensor to measure an ambient temperature. Based on the approximate temperature of the electronic device and the ambient temperature, the fan control circuit of the docking station can adjust the speed of one or more fans of the docking station. The fan control circuit can further adjust a cooler located in the docking station. The fan control circuit can further adjust power wirelessly provided to the electronic device. A temperature sensor and battery monitor in the electronic device can provide information to a policy enforcement circuit, which can further adjust these parameters.

Various embodiments of the present invention can incorporate one or more of these and the other features described herein. A better understanding of the nature and advantages of the present invention can be gained by reference to the following detailed description and the accompanying drawings.

### BRIEF DESCRIPTION OF THE DRAWINGS

FIG. 1 illustrates an electronic system according to an embodiment of the present invention;

FIG. 2 illustrates an electronic system according to an embodiment of the present invention;

FIG. 3 illustrates an electronic device being cooled by a docking station according to an embodiment of the present invention;

FIG. 4 illustrates a docking station according to an embodiment of the present invention;

FIG. 5 illustrates a feedback loop for controlling a fan speed of a docking station according to an embodiment of the present invention;

FIG. 6 illustrates the operation of the feedback loop of FIG. 5;

FIG. 7 illustrates another feedback loop for controlling a fan speed of a docking station according to an embodiment of the present invention; and

FIG. 8 illustrates the operation of the feedback loop of FIG. 7.

### DESCRIPTION OF ILLUSTRATIVE EMBODIMENTS

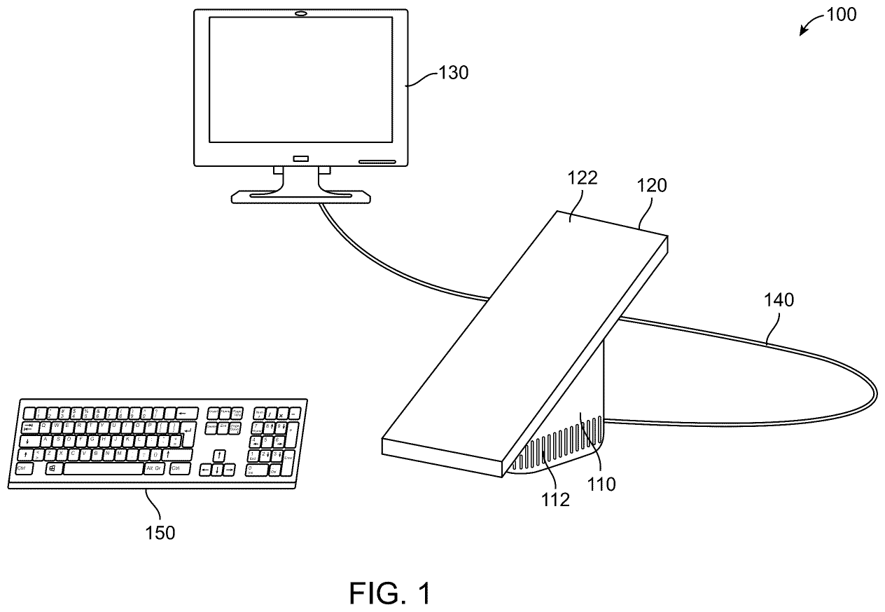

FIG. 1 illustrates an electronic system according to an embodiment of the present invention. This figure is shown for explanatory purposes and does not limit either the possible embodiments of the invention or the claims.

Electronic device 120 can be mounted on docking station 110 in electronic system 100. Docking station 110 can connect to monitor 130 through cable 132. Docking station 110 can communicate with keyboard 150 and other peripherals through a wireless network, such as a Bluetooth network. Docking station 110 can further include an ethernet connector (not shown) for communicating with a local area network. Docking station 110 can wirelessly communicate with electronic device 120. For example, docking station 110 can communicate with electronic device 120 using a Near-Field communication system, Wi-Fi, or other wireless protocol. Docking station 110 can alternatively communicate with electronic device 120 using a wired connection. For example, docking station 110 can communicate with electronic device 120 using USB Type-C or other wired protocol.

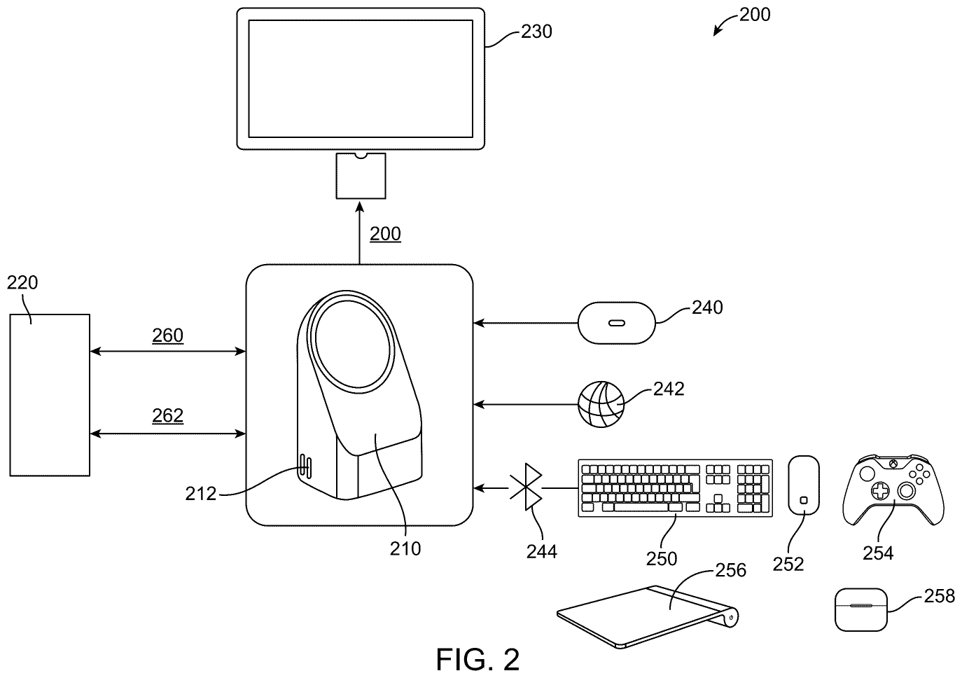

In this example, monitor 130, keyboard 150, and other devices, such as mouse 252, game controller 254, trackpad 256, headphones or earbud devices 258 (shown in FIG. 2) and other devices, can connect to docking station 110 directly, either wirelessly or through wires. Docking station 110 can then in turn connect to electronic device 120. This arrangement can allow a user to quickly connect an electronic device 120 to the entire system. It can also allow other users to quickly connect their electronic device 120 to the entire system as well.

An amount of power dissipated by electronic device 120 can be very high in electronic system 100. For example, the amount of graphics data provided by electronic device 120 to monitor 130 can be quite large. This amount of data transfer can drive power dissipation in the providing electronic device 120. Also, any programs or applications run on electronic device 120 can further drive power dissipation.

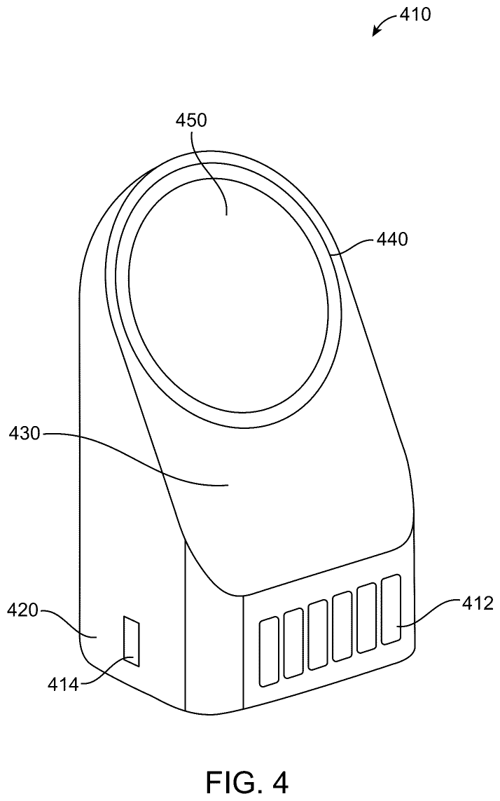

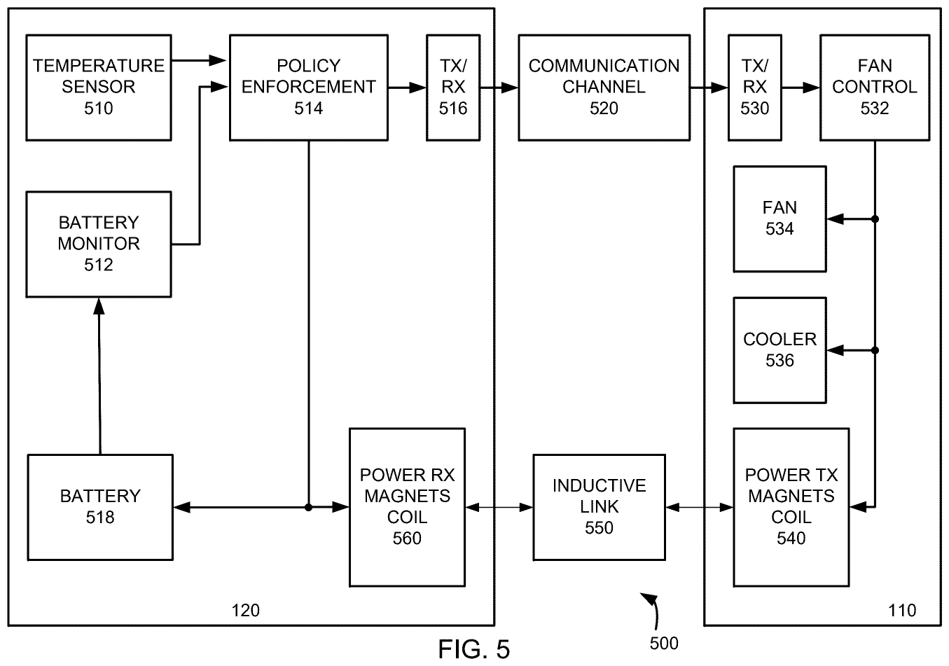

Accordingly, docking station 110 can move air across electronic device 120. This heat removal can allow electronic device 120 to operate at a higher power dissipation than would otherwise be possible. This can help to reduce the throttling of the performance of electronic device 120. Docking station 110 can draw air in through openings 112 and can drive to be air out of contacting surface 450 (shown in FIG. 4.) Docking station 110 can further include a cooler 536 (shown in FIG. 5) to further enable higher power dissipation. Docking station 110 can further receive graphics data from electronic device 120. This transfer of graphics data can be wireless or wired. Docking station 110 can support one or more connectors (not shown) that can accept connectors on cable 140 for driving monitor 130. By providing cooling to electronic device 120 and by providing a connector for driving monitor 130, docking station 110 can help to overcome limitations imposed by the small form factor of electronic device 120.

Electronic device 120 and docking station 110 can have an initial handshaking routine when powered up and connected. For example, electronic device 120 can inform docking station 110 that it is in a case. This can inform docking station 110 that it will likely need to run the one or more fans 534 (shown in FIG. 5) to achieve the same amount of cooling. Docking station 110 can identify what type of docking station it is to the electronic device 120. Electronic device 120 can determine how much cooling docking station 110 can provide and from that the electronic device 120 can estimate a maximum permissible power dissipation.

When electronic device 120 provides graphics data on cable 132 to monitor 130, the screen 122 of electronic device 120 might not be used and can be dimmed or turned off to further reduce power dissipation in electronic device 120.

Docking station 110 can facilitate other types of electronic systems that include other types of electronic devices. An example is shown in the following figure.

FIG. 2 illustrates an electronic system according to an embodiment of the present invention. Electronic system 200 can include docking station 210, electronic device 220, and monitor 230. Monitor 230 can be connected to docking station 210 via cable 232. Docking station 210 can include one or more connectors 214.

Docking station 210 can communicate with electronic device 220 wirelessly over channel 260. Channel 260 can be a Near-Field protocol, Wi-Fi, or other wireless protocol. Channel 260 can instead be a wired communication channel. For example, channel 260 can be a wired USB Type-C cable. Docking station 210 can provide power over inductive channel 262. For example, docking station 210 can include a coil to inductively transfer power to a corresponding coil in electronic device 220. To align these coils, docking station 210 can include one or more magnets to align with a corresponding one or more magnets in electronic device 220.

Docking station 210 can receive power over a connector, such as a USB type C connector 240. Docking station 210 can communicate with a local area network over ethernet connection 242. Docking station 210 can communicate with various accessories over Bluetooth connection 244. These devices can include keyboard 250, mouse 252, game controller 254, trackpad 256, headphones or earbud devices 258, as well as other devices, such as a camera, security device, remote sensors, and other types of devices (not shown.)

Again, electronic device 220 might need to be cooled in order to avoid performance throttling in electronic system 200. An example is shown in the following figure.

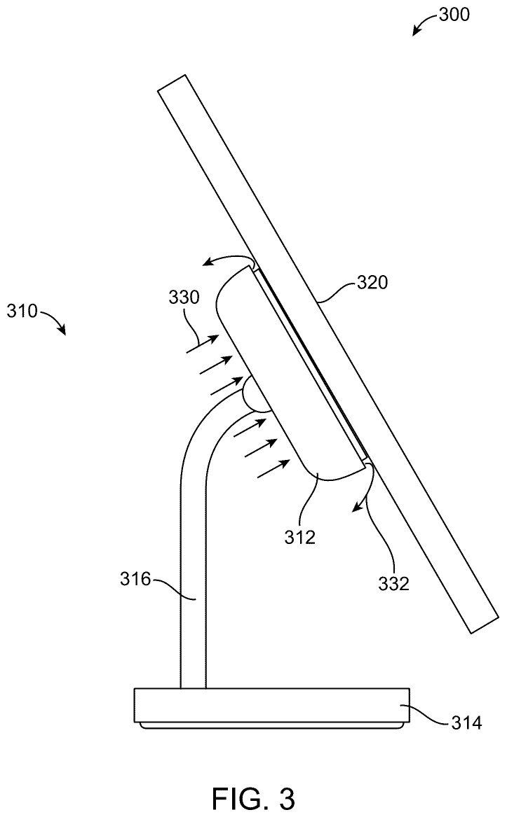

FIG. 3 illustrates an electronic device being cooled by a docking station according to an embodiment of the present invention. Electronic system 300 includes docking station 310 and electronic device 320. Docking station 310 can include base 314, arm 316, and attachment head 312. Attachment head 312 can be attached to a back of electronic device 320. Attachment head 312 can include one or more fans 534 (shown in FIG. 5.) Attachment head 312 can provide an airflow against a back of electronic device 320. This airflow can be directed towards a portion of electronic device 320 that is expected to dissipate a high amount of power. Attachment head 312 can include one or more magnets that can be attracted to one or more corresponding magnets in electronic device 320. Attachment head 312 can draw air 330 in through openings (not shown.) The air can reach a back of electronic device 320 and be vented away as air 332.

FIG. 4 illustrates a docking station according to an embodiment of the present invention. Docking station 410 can include housing 420. Housing 420 can include a number of openings 412 to provide a first portion of a ventilation path. Housing 420 can include a number of connectors 414 for receiving power, providing graphics data, and for other purposes. Housing 420 can include contacting surface 450 supported by frame 440. Contacting surface 450 can be permeable to provide a second portion of a ventilation path. Docking station 410 can include angled face 430. Angled face 430 can provide a tilted orientation for an electronic device when the electronic device is mated with docking station 410.

Docking station 410 can include one or more fans 534 (shown in FIG. 5) to pass air over some or all of electronic device 120 (shown in FIG. 1) to provide cooling when electronic device 120 is mounted on docking station 410. With this cooling, electronic device 120 can maintain a higher computational performance without being throttled by the policies of electronic device 120. For example, docking station 410 can include fan 534 that draws air from openings 412 in docking station 410 and moves air towards electronic device 120. The air can be directed towards a portion of electronic device 120 that is expected to be heated the most. The air can emerge from openings (not shown) in docking station 410 near electronic device 120. For example, the air can emerge from contacting surface 450 that mates with electronic device 120. Contacting surface 450 can be permeable to allow air flow. For example, contacting surface 450 can be a mesh, cloth, plastic with holes, or other permeable material. Contacting surface 450 can provide a high stiction, for example it can be include an adhesive or other material.

In another example, docking station 410 can include a fan that draws air from openings in contacting surface 450 and moves air towards openings 412 in docking station 410. Contacting surface 450 can be a mesh, cloth, plastic with holes, or other permeable contacting surface. The air can be directed pulled from near a portion of electronic device 120 that is expected to be heated the most. The air can emerge from openings 412 in docking station 410.

In these and other embodiments of the present invention, docking station 410 can include more than one fan 534. For example, docking station 410 can include a first fan 534 that draws air from openings in docking station 410 and a second fan 534 that moves air towards electronic device 120. The air can be directed by the second fan 534 towards a portion of electronic device 120 that is expected to be heated the most. The air can emerge from openings in docking station 410 near electronic device 120. For example, the air can emerge from contacting surface 450 that mates with electronic device 120. Contacting surface 450 can be permeable to allow air flow. For example, contacting surface 450 can be a mesh, cloth, plastic with holes, or other permeable contacting material.

In another example, docking station 410 can include a first fan 534 that draws air from openings in contacting surface 450 and a second fan 534 that moves air towards openings in docking station 410. Contacting surface 450 can be a mesh, cloth, plastic with holes, or other permeable contacting surface. Air can be directed pulled by the first fan 534 from near a portion of electronic device 120 that is expected to be heated the most. The air can be moved by the second fan 534 to emerge from openings 412 in docking station 410.

These and other embodiments of the present invention can include other cooling components as well. For example, docking station 410 can include a thermoelectric cooler 536 or other type of cooler. For example, docking station 410 can include a Peltier or other type of cooler. This cooler 536 can be used to cool the air being delivered to electronic device 120 by the one or more fans 534 of docking station 410.

These and other embodiments of the present invention can provide feedback loops for controlling fan 534. Such a feedback loop can adjust fan 534, read a temperature, readjust fan 534, and then reread the temperature in a loop. This can be more efficient than simply running a fan at high speed an entire time, which can cause excess noise and waste power. Examples are shown in the following figures.

FIG. 5 illustrates a feedback loop for controlling a fan speed of a docking station according to an embodiment of the present invention. Electronic system 500 can include docking station 110 and electronic device 120. In this example, electronic device 120 can direct docking station 110 to run fan 534 at a particular speed.

Electronic device 120 can include temperature sensor 510. Temperature sensor 510 can measure a temperature inside electronic device 120. Battery monitor 512 can monitor a state of battery 518. Policy enforcement circuit 514 can receive temperature information from temperature sensor 510. Policy enforcement circuit 514 can further receive information regarding a state of the battery 518 from battery monitor 512. Policy enforcement circuit 514 can receive other information, such as information regarding current and upcoming activities to be performed by electronic device 120.

Policy enforcement circuit 514 can receive this information and can make several determinations. For example, policy enforcement circuit 514 can determine an expected power dissipation for electronic device 120 based at least on current and upcoming activities to be performed by electronic device and an expected charging rate of battery 518. Policy enforcement circuit 514 can use this information, along with other information regarding an environment in which electronic device 120 is situated and a type of docking station 110 that electronic device 120 is mated with, to determine a speed of fan 534 in docking station 110. The information regarding an environment in which electronic device 120 is situated can include whether electronic device 120 is in a case. Various types of docking station 110 can include docking stations that surround electronic device 120 and are capable of providing airflow at several sides of electronic device 120. Docking station 110 can also be the same as or similar to docking station 110 in FIG. 1, docking station 310 in FIG. 3, or docking station 410 in FIG. 4. That is, parameters of policy enforcement circuit 514 can be based at least in part on a type of docking station 110 being used. For example, a maximum power dissipation can be increased when electronic device 502 is sitting enclosed in a docking station 504 that directs fans to several surfaces of electronic device 502.

Once policy enforcement circuit 514 determines a speed for fan 534, policy enforcement circuit 514 can transmit this information using transmitter 516. Transmitter 516 can be a wireless transmitter, such as a Near-Field transmitter, Wi-Fi, Bluetooth, or other type of wireless transmitter. This information can be conveyed over wireless (or wired) communication channel 520 and received by receiver 530 in docking station 110. Receiver 530 can be a corresponding wireless transmitter, such as a Near-Field transmitter, Wi-Fi, Bluetooth, or other type of wireless transmitter. and can provide the information to the fan control 532 in docking station 110. Fan control 532 can adjust a speed of fan 534. As before, docking station 110 can include more than one fan 534. The information from policy enforcement circuit 514 can also be used to adjust cooler 536. Cooler 536 can be a thermoelectric cooler, such as a Peltier cooler.

Information from policy enforcement circuit 514 can also be used to adjust a charging rate at which docking station 110 charges electronic device 120. For example, policy enforcement circuit 514 can include a lookup table (not shown) that can use a temperature of electronic device 502 and the charging voltage to determine a rate at which the battery can be charged. If battery 518 is near a full charge, it can be desirable to reduce a charging rate for battery 518 to reduce power dissipation of electronic device 120. When battery 518 is substantially discharged, it can be desirable to increase a speed of fan 534 and allow battery 518 to be charged at a higher rate. This information can be provided by electronic device 120 to docking station 110 via communication channel 520 or through inductive link 550.

Docking station 110 can include power transmitter 540, which can include one or more magnets and a coil. Electronic device 120 can include power receiver 560, which can include one or more magnets and a coil. The coil in power transmitter 540 can inductively couple through inductive link 550 with a corresponding coil in power receiver 560. To align coils for inductive power transmission, docking station 110 and electronic device 120 can each include one or more magnets.

Policy enforcement circuit 514 can further be anticipatory in nature. For example, if electronic device 502 detects that game controller 254 is being connected, policy enforcement circuit 514 can determine, based on user history, that a game is about to be played and the one or more fans 534 in docking station 504 can be turned on.

Docking station 110 and electronic device 120 can communicate in various ways. For example, when electronic device 120 transmits high-speed graphics data to docking station 110, electronic device 120 can use high speed wired or wireless communications. Docking station 110 and electronic device 120 can communicate using Wi-Fi, Near-Field communication, or other types of wireless communication. Docking station 110 and electronic device 120 can each include an interface that includes one or more antennas for high-speed Near-Field communication. An example of such an interface and antennas can be found in U.S. provisional patent application No. 63/700,135, filed Sep. 27, 2024, which is incorporated by reference. Docking station 110 and electronic device 120 can instead communicate using a wired connection, such as Universal Serial Bus Type-C or other high-speed wired communication. These signals can be routed between electronic device 120 and docking station 110 using cables having plugs that are inserted into receptacles in each device. These signals can be routed between electronic device 120 and docking station 110 using contacts that are included on a surface of each device.

These communication channels can be used as communication channel 520, or communication channel 520 can be a separate communication channel. Communication channel 520 can be a dedicated communication channel for the thermal control provided by docking station 110, or other circuits in electronic device 120 and docking station 110 can communicate using communication channel 520. The requirements for transferring data for thermal control can be lower than those for transferring graphics data to a monitor. Accordingly, when communication channel 520 is limited to transferring thermal control and similar data, the requirements for transmitter/receiver 516 and transmitter/receiver 530 can be reduced. Accordingly transmitter/receiver 516 and transmitter/receiver 530 can transmit wireless signals over communication channel 520. These signals can be Wi-Fi, Bluetooth, Near-Field, and other types of wireless data transmission. These signals can instead be wired signals. For example, these signals can be Universal Serial Bus signals, Universal Serial Bus Type-C signals, or other types of signals. These signals can be routed between electronic device 120 and docking station 110 using cables having plugs that are inserted into receptacles in each device. These signals can be routed between electronic device 120 and docking station 110 using contacts that are included on a surface of each device.

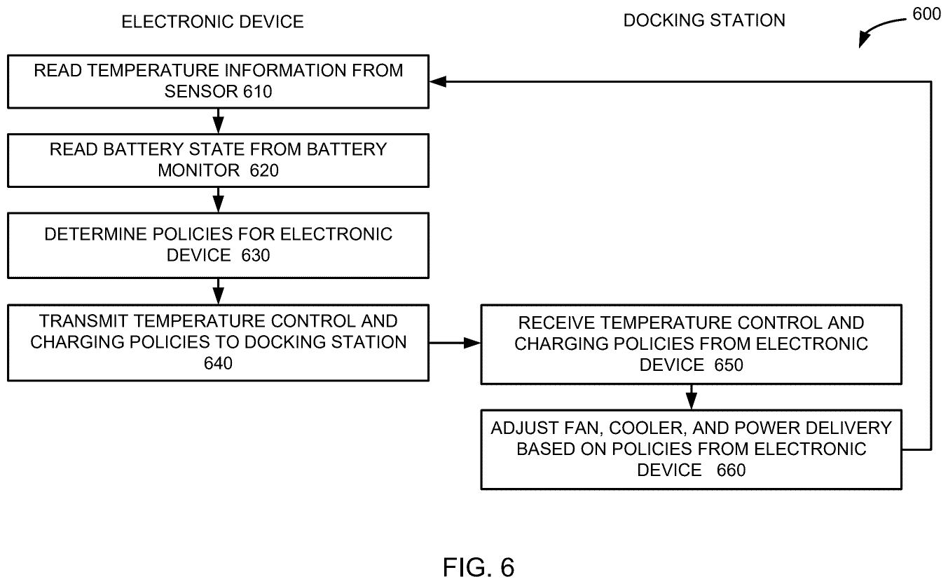

FIG. 6 illustrates the operation of the feedback loop of FIG. 5. In act 610, an electronic device can read temperature information from a sensor. In act 620, the electronic device can read battery state information from a battery monitor. Policies for power use can be determined in act 630. These policies can include temperature control and battery charging policies. These temperature control and battery charging policies can be transmitted to a docking station in act 640.

In act 650, the temperature control and charging policies can be received from the electronic device by the docking station. The docking station can adjust the one or more fans, cooler, and power delivery or charging rate provided by the docking station in act 660. In this example, the feedback loop is closed, and again, in act 610, the electronic device can read temperature information from a sensor, and the loop can repeat.

In the above examples, and electronic device can control the operation of fans, coolers, and charging circuitry in a docking station. In these and other embodiments of the present invention, the docking station can take on more of these responsibilities. An example is shown in the following figures.

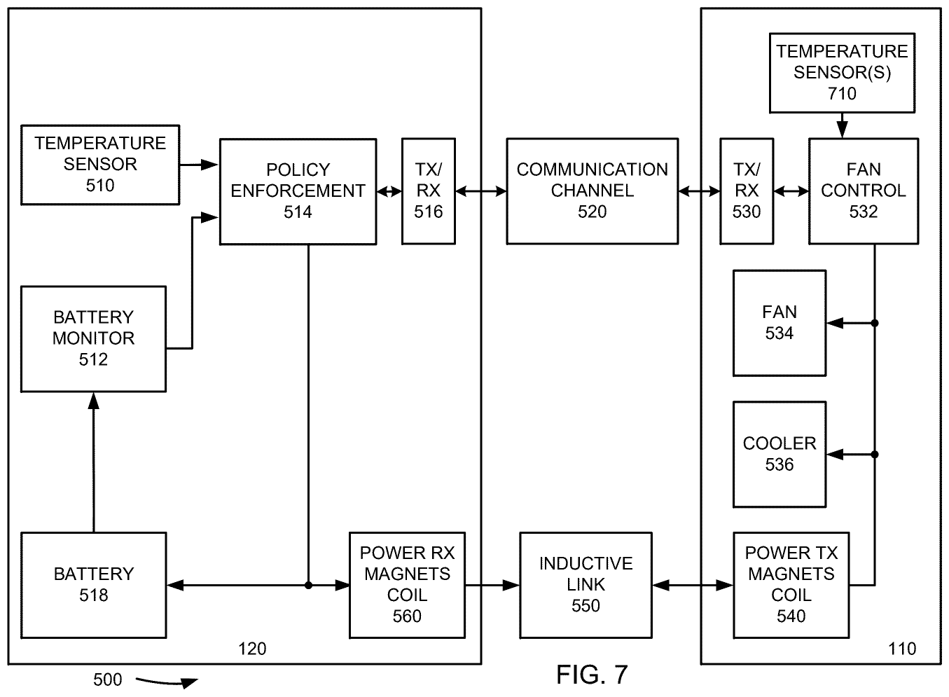

FIG. 7 illustrates another feedback loop for controlling a fan speed of a docking station according to an embodiment of the present invention. Electronic system 500 can include electronic device 120 and docking station 110. Docking station 110 can include one or more temperature sensors 710. For example, docking station 110 can include a temperature sensor 710 positioned in docking station 110 to be near electronic device 120. This can allow docking station 110 to be able to estimate a temperature of electronic device 120. From this, fan control 532 can use this temperature information to determine a speed of one or more fans 534. Fan control 532 can also adjust cooler 536.

Fan control 532 can also adjust a power delivery rate provided by power transmitter 540. Fan control 532 can receive battery state information from electronic device 120. Fan control 532 can use this information along with temperature information regarding electronic device 120 and can adjust power delivery to electronic device 120. Fan control 532 can receive battery state information through inductive link 550 or through wireless communication channel 520.

Docking station 110 can further include an additional temperature sensor for determining an ambient temperature. A difference between temperature information from the temperature sensor near electronic device 120 and the ambient temperature can provide an indication of the actual heating of electronic device 120.

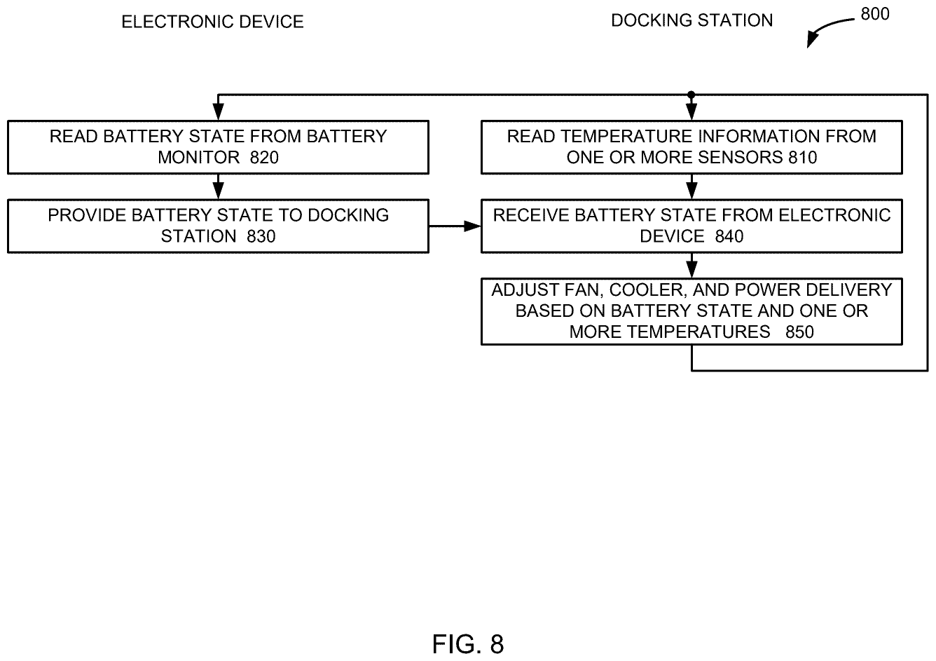

FIG. 8 illustrates the operation of the feedback loop of FIG. 7. In act 810, temperature information can be read from one or more temperature sensors by a docking station. In act 820, battery state information can be read from a battery monitor by the electronic device. The battery state information can be provided by the electronic device to the docking station in act 830.

In act 840, the battery state information can be received from the electronic device by the docking station. The docking station can adjust one or more fans, a cooler, and power delivery based on the battery state and the one or more temperatures. This loop can be closed, such that the docking station can reread temperature information from one or more sensors in act 810, and battery state information can be reread from the battery monitor of the electronic device in act 820.

Reference numbers are used in a consistent manner throughout the specification.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The above description of embodiments of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications to thereby enable others skilled in the art to best utilize the invention in various embodiments and with various modifications as are suited to the particular use contemplated. Thus, it will be appreciated that the invention is intended to cover all modifications and equivalents within the scope of the following claims.

What is claimed is:

1. A docking station comprising:
a housing having a bottom surface;
a contacting surface on the housing, the contacting surface to mate with an electronic device when mounted on the docking station, wherein the contacting surface is permeable to form a first portion of a ventilation path;
a plurality of openings in the housing to form a second portion of the ventilation path;
a first connector at a surface of the housing to receive power from an external source;
a second connector at a surface of the housing to provide video signals to a monitor;
a first fan under the contacting surface on the housing, the first fan supported by the housing;
a magnet under the contacting surface and supported by the housing, the magnet to magnetically attach the electronic device when mounted on the docking station;
a charging coil under the contacting surface and supported by the housing, the charging coil to wirelessly provide power to the electronic device when mounted on the docking station;
a first circuit and a first antenna to wirelessly communicate with the electronic device when mounted on the docking station; and
a second circuit and a second antenna to wirelessly communicate with a graphics input device.

2. The docking station of claim 1 wherein when the first fan is running, the first fan draws air from the plurality of openings in the housing towards the permeable contacting surface.

3. The docking station of claim 1 wherein when the first fan is running, the first fan draws air from the permeable contacting surface and towards the plurality of openings in the housing.

4. The docking station of claim 1 further comprising a cooler supported by the housing.

5. The docking station of claim 4 wherein the cooler is a Peltier cooler.

6. The docking station of claim 1 further comprising an ethernet connector on the housing and circuitry for communicating with one or more external electronic devices using the ethernet connector.

7. The docking station of claim 1 wherein the contacting surface and the bottom surface of the housing form an obtuse angle.

8. The docking station of claim 1 wherein the magnet comprises a magnet array.

9. The docking station of claim 8 wherein the first antenna is positioned under the contacting surface.

10. The docking station of claim 9 wherein the second circuit is a Bluetooth circuit and the second antenna is a Bluetooth antenna.

11. The docking station of claim 10 further comprising a first temperature sensor to read a temperature of the docking station near the contacting surface and a second temperature sensor to read an ambient temperature near the docking station.

12. The docking station of claim 11 further comprising a second fan supported by the housing.

13. A method of operating an electronic system comprising an electronic device and a docking station, the method comprising:
with a first temperature sensor on the electronic device, reading a temperature of the electronic device;
with a battery monitor on the electronic device, reading a state of a battery of the electronic device;
with the electronic device, determining one or more policies for the operation of the electronic device, the one or more policies comprising temperature control and charging policies;
with the electronic device, transmitting the temperature control and charging policies to the docking station;
with the docking station, receiving the temperature control and charging policies from the electronic device; and
adjusting a speed of a fan of the docking station based at least in part on the temperature control and charging policies from the electronic device.

14. The method of claim 13 further comprising adjusting a power delivered from the docking station to the electronic device.

15. The method of claim 14 further comprising adjusting a cooler of the docking station based at least in part on the temperature control and charging policies from the electronic device.

16. The method of claim 15 further comprising, with the docking station, reading an ambient temperature with a second temperature sensor and adjusting the speed of the fan of the docking station based at least in part on the ambient temperature.

17. A method of operating an electronic system comprising an electronic device and a docking station, the method comprising:
with a first temperature sensor on the docking station, reading a temperature of the docking station near the electronic device;
with a battery monitor on the electronic device, reading a state of a battery of the electronic device;
with the electronic device, providing the state of the battery of the electronic device to the docking station;
with the docking station, receiving the state of the battery of the electronic device with the docking station; and
adjusting a speed of a fan of the docking station based at least in part on the temperature of the docking station near the electronic device and the state of the battery of the electronic device.

18. The method of claim 17 further comprising adjusting a power delivered from the docking station to the electronic device based at least in part on the temperature of the docking station near the electronic device and the state of the battery of the electronic device.

19. The method of claim 18 further comprising adjusting a cooler of the docking station based at least in part on the temperature of the docking station near the electronic device and the state of the battery of the electronic device.

20. The method of claim 19 further comprising, with the docking station, reading an ambient temperature with a second temperature sensor and adjusting the speed of the fan of the docking station based at least in part on the ambient temperature.
